(19) United States
(12) Patent Application Publication
(10) Pub. No.: US 2006/0194390 A1
(43) Pub. Date: Aug. 31, 2006

(54) Semiconductor device and method of manufacturing the same

(76) Inventors: Yutaka Imai, Tokyo (JP); Yoshiyuki Ishigaki, Tokyo (JP)

Correspondence Address: MCDERMOTT WILL & EMERY LLP, 600 13TH STREET, N.W., WASHINGTON, DC, 20005-3096, US

(21) Appl. No.: 11/355,177

(22) Filed: Feb. 16, 2006

(30) Foreign Application Priority Data
Feb. 16, 2005 (JP) 2005-039429

(51) Int. Cl. H01L 21/336; H01L 21/44; H01L 23/48

(52) U.S. Cl. 438/257; 438/597; 257/734

(57) ABSTRACT

A semiconductor device includes an interlayer insulation film including an air gap between portions of adjacent wiring layers or isolation pattern layers or both that are distanced from each other by thinning a layered structure of each of the wiring layers or the isolation pattern layers or both selectively from a top layer to a substrate so that the portions of the wiring layers or the isolation pattern layers or both are distanced from each other.

### BACKGROUND OF THE INVENTION

1. Field of the Invention

The present invention relates to a semiconductor device and a method of manufacturing the semiconductor device, and more particularly, to a semiconductor device including a non-volatile memory and a method of manufacturing the semiconductor device.

2. Description of the Related Art

A non-volatile memory cell includes assist gate electrodes in a flat-strip shape disposed in parallel on a semiconductor substrate, control gate electrodes perpendicular to the assist gate electrodes, and floating gate electrodes disposed in proximity to an intersection of a lattice formed by the assist gate electrodes and the control gate electrodes. In addition, an interlayer insulation film is formed between adjacent floating gate electrodes along the assist gate electrodes for an electrical isolation.

When a size of a memory cell is decreased, a gap between adjacent floating gate electrodes along of the assist gate electrodes decreases, which increases a parasitic capacitance between the floating gate electrodes. This causes a capacitance ratio of a parasitic capacitance between the control gate electrode and the floating gate electrode to the capacitance between the floating gate electrodes to be decreased, which results in a degradation of a coupling ratio between the control gate electrode and the floating gate electrode.

This will cause a controllability of a voltage of the floating gate electrodes by the control gate electrodes to be degraded. For instance, an enough speed of writing and deleting with respect to the memory cannot be obtained at with a low voltage, and a margin of a control voltage with which an operation of the memory can be performed stably becomes narrow.

A method for coping with the above problem is disclosed in, for example, Japanese Patent Application Laid-open No. H10-12730.

However, in the conventional technology disclosed in the above literature, a manufacturing process becomes complex because it is necessary to suitably control special conditions for depositing a film for forming an air gap only in a position where a distance between adjacent wiring layers is small.

### SUMMARY OF THE INVENTION

It is an object of the present invention to at least solve the problems in the conventional technology.

According to an aspect of the present invention, a semiconductor device includes an interlayer insulation film including an air gap between portions of adjacent wiring layers or isolation pattern layers or both that are distanced from each other by thinning a layered structure of each of the wiring layers or the isolation pattern layers or both selectively from a top layer to a substrate so that the portions of the wiring layers or the isolation pattern layers or both are distanced from each other.

According to another aspect of the present invention, a method for producing a semiconductor device which comprises an interlayer insulation film having an air gap between any one of adjacent wiring layers and isolation pattern layers disposed on a semiconductor substrate includes thinning the layered structures of at least one of the wiring layers and the isolation pattern layers selectively from a top layer to a base substrate surface by a wet etching process by using a difference in etching rates so that a distance is kept between at least one of the wiring layers and the isolation pattern layers from the top layer to the base substrate surface; and forming an interlayer insulation film having the air gap between at least one of the distanced wiring layers and the isolation pattern layers by laminating insulation films between at least one of the wiring layers and the isolation pattern layers.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIGS. 1A to 4C are schematics for illustrating a process for a method of manufacturing semiconductor device according to a first embodiment of the present invention;

FIGS. 5A and 5B are cross sections of a semiconductor device according to the first embodiment for illustrating an example of a wiring structure;

FIGS. 6A to 8C are schematics for illustrating a process for a method of manufacturing semiconductor device according to a second embodiment of the present invention;

FIGS. 9A and 9B are cross sections of a semiconductor device according to the second embodiment for illustrating an example of a wiring structure;

FIGS. 10A to 12C are schematics for illustrating a process for a method of manufacturing semiconductor device according to a fourth embodiment of the present invention; and

FIGS. 13A to 18C are schematics for illustrating a process for a method of manufacturing semiconductor device according to a fifth embodiment of the present invention.

### DETAILED DESCRIPTION OF THE PREFERRED EMBODIMENTS

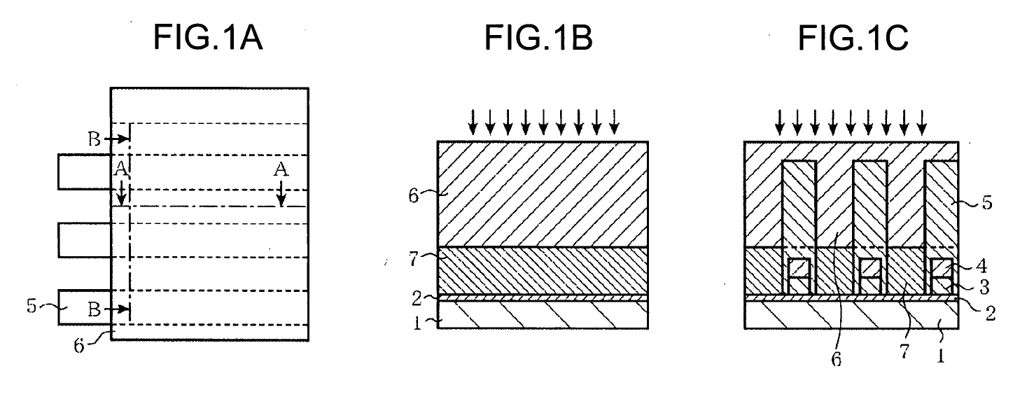

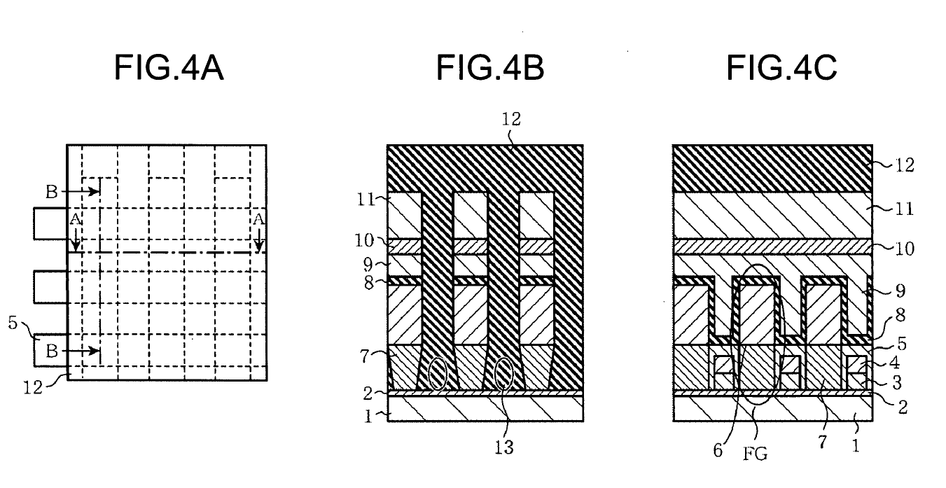

FIGS. 1A to 4C are schematics for illustrating a process for a method of manufacturing semiconductor device according to a first embodiment of the present invention. The process proceeds from a manufacturing process shown in FIGS. 1A to 1C to a manufacturing process shown in FIGS. 4A to 4C, taking a non-volatile memory as an example of the semiconductor device. Each of FIGS. 1A, 2A, 3A, and 4A is a top view of the semiconductor device, each of FIGS. 1B, 2B, 3B, and 4B is a cross section of the semiconductor device cut along a line A-A shown in respective FIGS. 1A, 2A, 3A, and 4A, and each of FIGS. 1C, 2C, 3C, and 4C is a cross section of the semiconductor device cut along a line B-B shown in Fig. respective FIGS. 1A, 2A, 3A, and 4A.

At the process shown in FIGS. 1A to 1C, impurities are injected to the bottom portion of the polysilicon layer, which is to serve as a floating gate electrode, near the silicon substrate.

After forming an oxide film 2 of silicon oxide and the like on the silicon substrate 1, conductive films 3, which are to serve as assist gate electrodes, are formed of polysilicon whose resistance has been reduced by impurity doping or the like. Each of the conductive films 3 is shaped like a strip disposed along the line A-A in FIG. 1A, and a plurality of conductive films are aligned in parallel along the line B-B.

Next, gate-covering nitride films 4 are formed of, for example, silicon nitride (such as Si₃N₄) in such a manner as to cover the conductive films 3. Thereafter, as shown in FIG. 1C, oxide film layers 5 are formed of silicon oxide or the like along each of the conductive films 3 to cover the side surfaces of the conductive films 3 as well as the top surfaces and side surfaces of the gate-covering nitride films 4.

After constituting the above-mentioned structure, as shown in FIGS. 1B and 1C, a polysilicon layer 6 is formed by the CVD (chemical vapor deposition) process or the like so as to function as a floating gate electrode unit. Following this, as indicated by the arrows in FIGS. 1B and 1C, impurities such as arsenic (As) and boron (B) are injected toward the bottom portion 7 of the polysilicon layer 6 which is close to the surface of the silicon substrate 1, with high energy by a conventional ion injection method or the like. The impurity concentration of the bottom portion 7 is thereby increased. For instance, a difference is created between the etching rates of the bottom portion 7 and the rest of the polysilicon layer 6 by injecting 1E15 or more of arsenic (As), boron (B), BF₂+ ions, or the like. The structure shown in FIGS. 1A to 1C is obtained with the above processing.

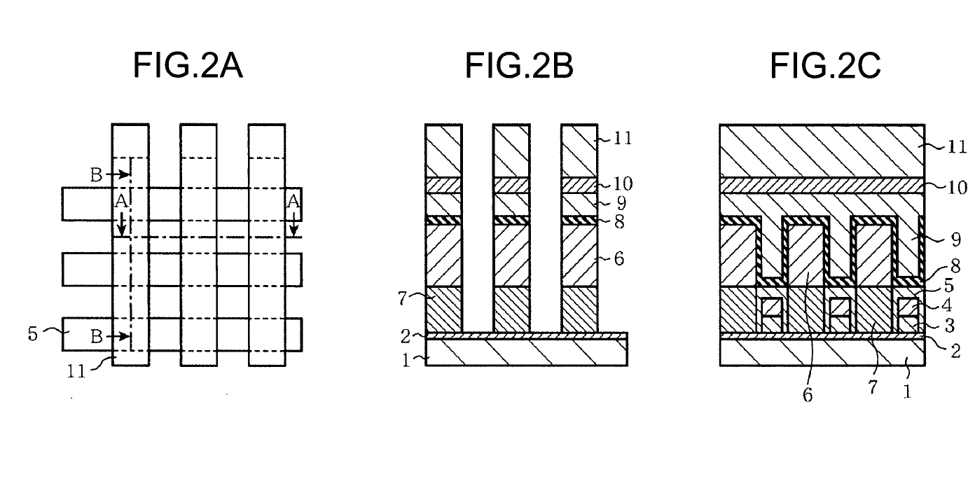

Next, at the step shown in FIG. 2A, control gate electrodes are formed.

After the step shown in FIG. 1C, the polysilicon is removed except for the portion of the polysilicon adjacent to the oxide film layer 5 by dry etching, and an ONO (oxide film-nitride film-oxide film) insulation film 8 is formed on top of this film. Thereafter, a polysilicon layer 9 is formed on top of the ONO insulation film 8 by the CVD process or the like On top thereon is formed a conductive film 10 of polysilicon that has a lowered resistance. Furthermore, an oxide film 11 is formed thereon and etched into patterns of control gate electrodes. The structure shown in FIGS. 2B and 2C is thereby obtained.

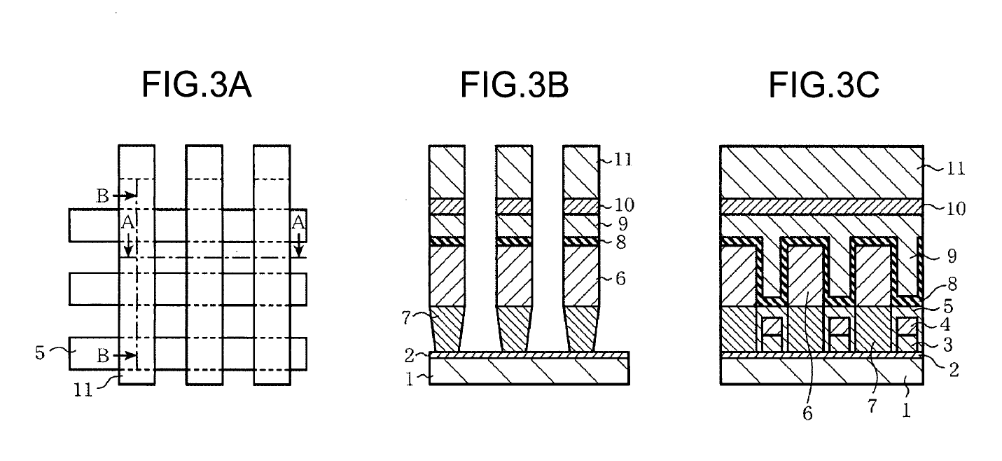

Then, at the step shown in FIG. 3A, the polysilicon film layer, which is to serve as a floating gate electrode unit, is etched selectively at its bottom portion close to the silicon substrate.

First, the highly doped bottom portions 7 of the polysilicon layer 6 that has been exposed at the steps of FIGS. 2A to 2C are selectively etched by wet etching. An etching rate ratio of 3 to 1 can be attained by using, for example, a mixture of ammonium fluoride and hydrofluoric acid. Owing to the difference in etching rates, only the bottom portions 7 are thinned, as shown in FIG. 3B.

Then, an interlayer insulation film 12 is formed at the step shown in FIG. 4A. Here, because the inverse-tapered bottom portions 7 are kept at a certain distance from each other, air gaps 13 are formed between the bottom portions 7 as shown in FIG. 4B, even when the interlayer insulation film 12 is formed under a film forming condition that has an excellent coverage such as the CVD process, unlike the conventional technology. Further, the circled portion in FIG. 4C is to function as a floating gate electrode FG.

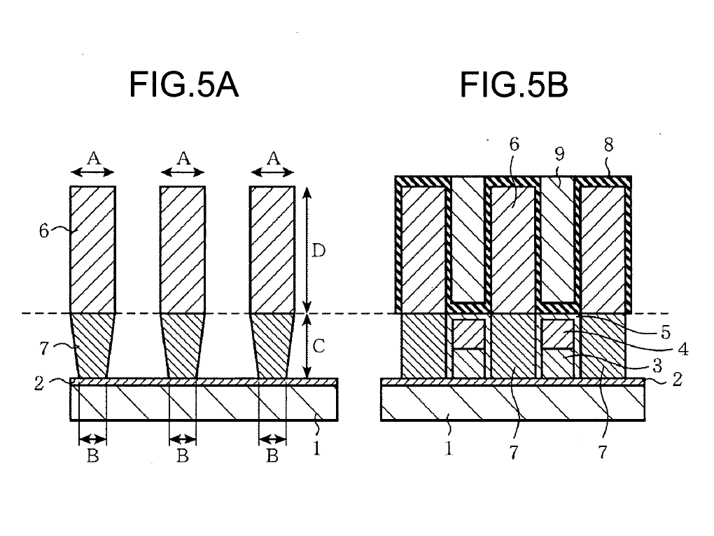

Regarding a suitable dimensional relationship between the polysilicon layer 6 and its bottom portion 7, given that the widths of the polysilicon layer 6 and bottom portion 7 are A and B, respectively, the height of the bottom portion 7 from the oxide film 2 is C, and the height of the polysilicon layer 6 from the bottom portion 7 is D, as shown in FIG. 5A, the inverse-tapered bottom portion 7 is shaped in such a manner as to satisfy approximately A:B=10.8:10.4. In addition, the wet etching process on the portion of the polysilicon layer 6 that is above the bottom portion 7, in other words, the portion of the floating gate electrode that is brought into contact with the ONO insulation film 8, is controlled so that the layered structure perpendicular to the silicon substrate 1 will not lose balance and reduce the contact area.

With such a dimensional relationship, the parasitic capacitance between the contact portions of the ONO insulation films 8 and floating gate electrodes is maintained, while the parasitic capacitance between the bottom portions 7, i.e., between the floating gate electrodes, is lowered. Because the capacity ratio of the parasitic capacitance between the control gate electrodes to the parasitic capacitance between the floating gate electrodes is increased, the coupling ratio of the control gate electrodes to the floating gate electrodes can be improved.

As described above, according to the first embodiment, adjacent floating gate electrode layers are formed, impurities such as arsenic and boron are injected to the floating gate electrode layers between their top layers and the base substrate surface in order to promote the etching process, and the layered structures of the adjacent floating gate electrode layers are thinned selectively from the top layers to the base substrate surface by etching; thus, the coupling ratio between the control gate electrodes and floating gate electrodes is improved, and the controllability of the voltage of the floating gate electrodes being controlled by the control gate electrodes is improved. Hence, a memory with a large control voltage margin necessary for stable operation, which allows for, for instance, a sufficient speed of memory writing and erasing even at a low voltage, can be attained.

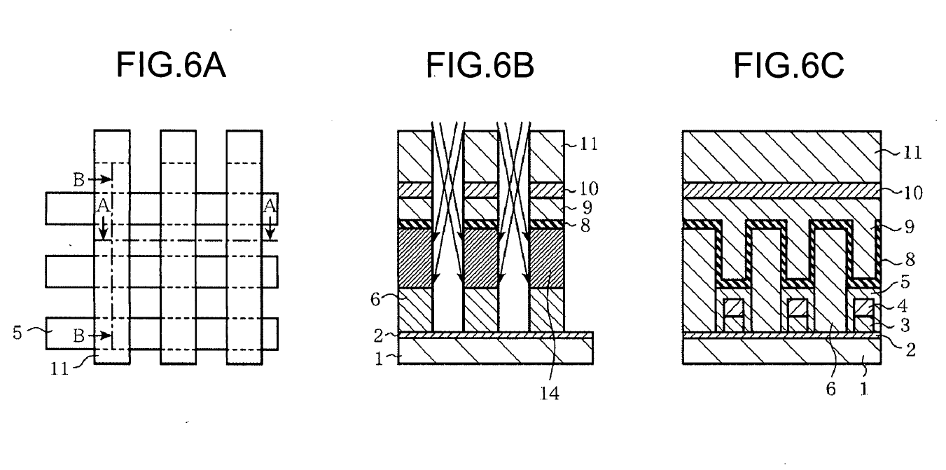

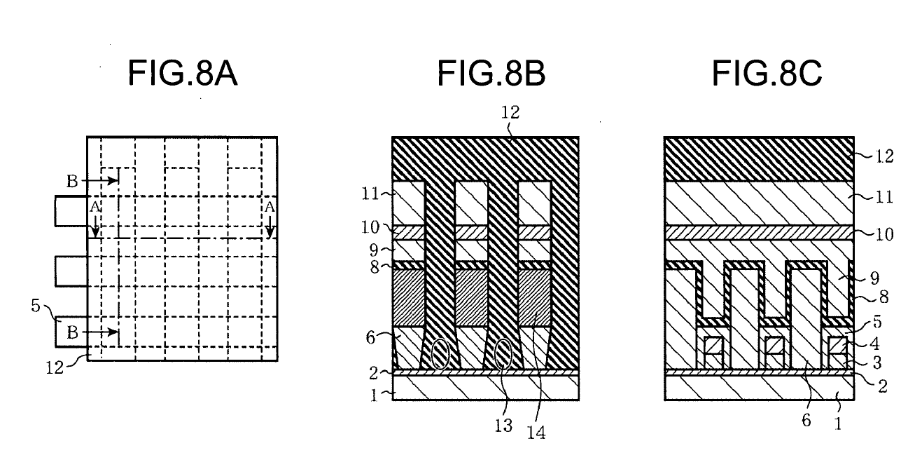

FIGS. 6A to 8C are views showing the constitutions at different steps of the method for producing a semiconductor device according to a second embodiment of the present invention; the process proceeds from the manufacturing step shown in FIG. 6A to the manufacturing step shown in FIG. 8C, taking a volatile memory as an example of a semiconductor device. Each of FIGS. 6A, 7A, and 8A is a top view of the semiconductor device, each of FIGS. 6B, 7B, and 8B is a cross section along a line A-A shown in respective FIGS. 6A, 7A, and 8A, and each of FIGS. 6C, 7C, and 8C is a cross section along a line B-B shown in respective FIGS. 6A, 7A, and 8A.

At the step shown in FIG. 6A, nitrogen, oxygen or the like is injected into a portion of the polysilicon film layer, which is to serve as a floating gate electrode, except for the bottom portion that is close to the silicon substrate.

In a similar manner to the first embodiment, after forming an oxide film 2 of silicon oxide or the like on the silicon substrate 1, conductive films 3, which are to serve as assist gate electrodes, are formed of polysilicon or the like the resistance of which has been lowered by impurity doping or the like. Each of the conductive films 3 is shaped like a strip along the line A-A shown in FIG. 6A, and a plurality of conductive films 3 are disposed in parallel along the line B-B.

Next, gate-covering nitride films 4 are formed of, for example, silicon nitride (such as Si₃N₄) in such a manner as to cover each conductive film 3. Thereafter, an oxide film layer 5 is formed of silicon oxide or the like in such a manner as to cover the side surface of the conductive film 3 and the top and side surfaces of the gate-covering nitride film 4, as shown in FIG. 6C. Following this, a polysilicon layer 6, which is to function as a floating gate electrode unit, is formed by the CVD (chemical vapor deposition) process or the like, as shown in FIGS. 6B and 6C.

After the above-mentioned constitution is formed, a portion of polysilicon except for the portion adjacent to the oxide film layer 5 is removed by dry etching, on which an ONO (oxide film-nitride film-oxide film) insulation film 8 is formed. Thereafter, a polysilicon layer 9 is disposed on the ONO insulation film 8 by the CVD process or the like. On top thereof is formed a conductive film 10 of polysilicon whose resistance has been lowered. Further, an oxide film 11 is formed on top of this structure, and etched into patterns of control gate electrodes.

Then, with the bottom portion of the floating gate electrode being exposed on the silicon substrate 1, argon, nitrogen, oxygen or the like is injected thereto from an oblique angle. Here, the injection is conducted only to the contact portion of the polysilicon layer 6 between the ONO insulation film 8 and targeted floating gate electrode to slow down the etching rate during the wet etching process, by adjusting the injection angle, to form an amorphous silicon portion 14. The constitution as shown in FIGS. 6B and 6C is thereby attained.

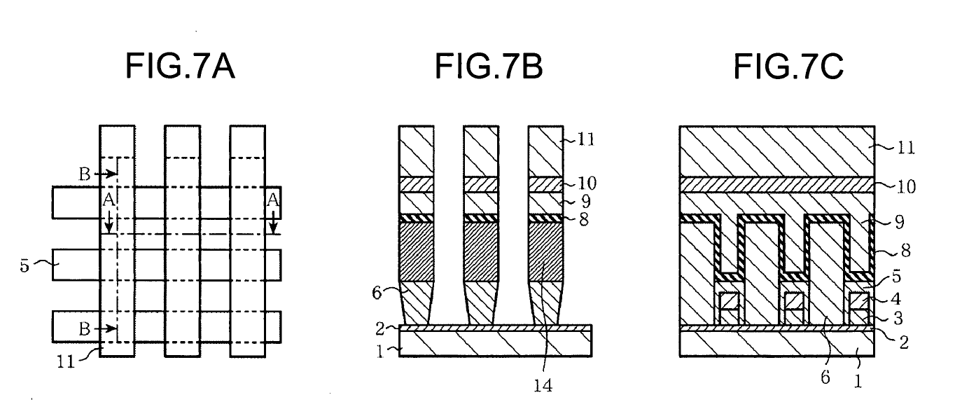

Following this, at the step shown in FIG. 7A, the polysilicon film layer, which is to serve as a floating gate electrode, is etched selectively at its bottom portion close to the silicon substrate.

First, the portion of the polysilicon layer which is not doped with argon, nitrogen, oxygen or the like and not brought into an amorphous state is selectively etched. The use of a mixture of ammonium fluoride and hydrofluoric acid, for instance, makes the etching rate ratio 2:1. The shape of the amorphous portion 14 of the polysilicon layer is thereby maintained, while the bottom portion 6 of the polysilicon layer is thinned, as shown in FIG. 7B.

Then, an interlayer insulation film 12 is formed at the step shown in FIG. 8A. At this time, because the bottom portions 6 of the polysilicon layer are inverse-tapered tapered and are kept at a certain distance from each other, air gaps 13 can be formed, as shown in FIG. 8B, even if the interlayer insulation films 12 are formed under film forming conditions with an excellent coverage such as the CVD process, unlike the conventional technology.

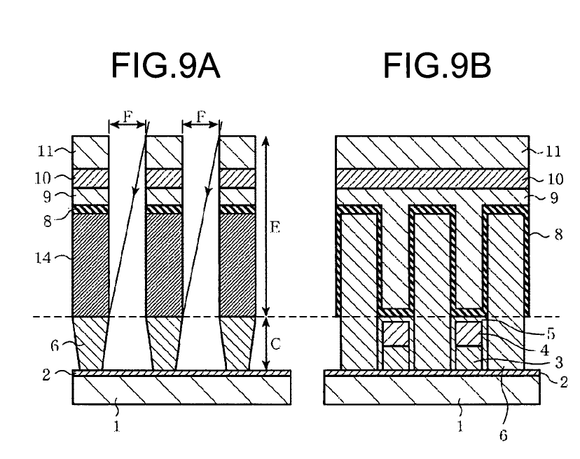

It should be noted that during the process of injecting argon, nitrogen or oxygen shown in FIGS. 6A to 6C, the injection is directed at the targeted area by way of shadowing. More specifically, when the height of the portion of the polysilicon layer 6 that is below the contact portibn of the ONO insulation film 8 and the floating gate electrode is C, the height of the upper portion above this is E, and the distance between the wiring layers including the polysilicon layers 6 is F, as shown in FIG. 9A, the injection angle θ is θ=tan (E/F).

As a result, the shape perpendicular to the silicon substrate 1 is maintained for the silicon portion 14 which has been brought into an amorphous state by injecting argon, nitrogen or oxygen, that is the contact portion of the ONO insulation film 8 and the floating gate electrode, while the bottom portion 6 of the polysilicon layer below the portion 14 is thinned, as shown in FIGS. 9A and 9B.

By this process, the parasitic capacitance between the contact portions of the ONO insulation film 8 and floating gate electrodes is maintained, while the parasitic capacitance between the floating gate electrodes is reduced. This increases the capacity ratio between the capacitance between the control gate electrodes and the capacitance between the floating gate electrodes, and thus the coupling ratio of the control gate electrodes and floating gate electrodes can be improved.

As described above, according to the second embodiment, floating gate electrode layers are formed adjacent to each other, impurities such as nitrogen and oxygen are injected to the upper layer portion of each of the adjacent floating gate electrode layers whose layered structure should not be thinned, so as to bring the portion into an amorphous state and delay the etching process, and the layered structure of each of the adjacent floating gate electrode layers is selectively thinned from the upper layer to the base substrate surface; as a result, the coupling ratio of the control gate electrodes and floating gate electrodes is improved, and the controllability of the voltage of the floating gate electrodes by the control gate electrodes is improved. Hence, a memory with a large margin for the control voltage that stabilizes the operation can be attained, allowing for, for example, a sufficient speed of memory writing and erasing even at a low voltage.

A third embodiment according to the present invention provides an example of improving the etching rate ratio for the portion to be selectively etched, by combining and conducting the processes of the first and the second embodiments.

First, in a similar manner to FIG. 1A described in the first embodiment, after forming an oxide film 2 of silicon oxide and the like on the silicon substrate 1, conductive films 3, which are to serve as assist gate electrodes, are formed of polysilicon whose resistance has been reduced by impurity doping or the like. Next, gate-covering nitride films 4 are formed of, for example, silicon nitride (such as Si₃N₄) in such a manner as to cover the conductive films 3. Thereafter, as shown in FIG. 1C, oxide film layers 5 are formed of silicon oxide or the like along each of the conductive films 3 to cover the side surfaces of the conductive films 3 as well as the top surfaces and side surfaces of the gate-covering nitride films 4.

After constituting the above-mentioned structure, as shown in FIGS. 1B and 1C, a polysilicon layer 6 is formed by the CVD (chemical vapor deposition) process or the like so as to function as a floating gate electrode unit. Following this, in a similar manner to the first embodiment impurities such as arsenic (As) and boron (B) are injected toward the bottom portion of the polysilicon layer 6 which is close to the surface of the silicon substrate 1, with high energy by a conventional ion injection method or the like. The impurity concentration of the bottom portion is thereby increased. A difference is created in the etching rates with respect to the rest of the polysilicon layer 6, by injecting, for instance, 1E15 or more of arsenic (As), boron (B), BF₂+ ions, or the like.

Following this, in a similar manner to FIG. 2A described in the first embodiment, the polysilicon is removed except for the portion of the polysilicon adjacent to the oxide film layer 5 by dry etching, and an ONO (oxide film-nitride film-oxide film) insulation film 8 is formed on top of this film. Thereafter, a polysilicon layer 9 is formed on top of the ONO insulation film 8 by the CVD process or the like. On top thereon is formed a conductive film 10 of polysilicon that has a lowered resistance. Furthermore, an oxide film 11 is formed thereon and etched into patterns of control gate electrodes.

Next, in a similar manner to FIG. 6A described in the second embodiment, with the bottom portion of the floating gate electrode being exposed on the silicon substrate 1, argon, nitrogen, oxygen or the like is injected thereto from an oblique angle. Here, an amorphous silicon portion 14 is formed by adjusting the injection angle so that the injection is conducted on, of the polysilicon layer 6, only the contact portion between the ONO insulation film 8 and the floating gate electrode, which is the targeted portion for slowing down the etching rate during the wet etching process.

With the above process, impurities such as arsenic (As), boron (B), BF₂+ ions, and the like are injected to the portion of the polysilicon layer 6 close to the surface of the silicon substrate 1, while argon, nitrogen, oxygen or the like is injected to the portion above this portion, which corresponds to the contact portion of the ONO insulation film 8 and the floating gate electrode, to bring it into an amorphous state.

Then, an etching process is conducted by way of wet etching, selectively on the portion of the polysilicon layer 6 that is not doped with argon, nitrogen, oxygen or the like to be brought into an amorphous state but is doped with impurities such as arsenic (As), boron (B), BF₂+ ions and the like to transform into a diffusion layer. The use of a mixture of ammonium fluoride and hydrofluoric acid, for instance, can set the etching rate ratio to 6:1. This results in the shape of the amorphous portion of the polysilicon layer being maintained and only the bottom portion of the polysilicon layer 6 being thinned, as shown in FIGS. 3B and 7B.

Thereafter, an interlayer insulation film 12 is formed in a similar manner to FIG. 4A described in the first embodiment and FIG. 8A described in the second embodiment. At this time, because the bottom portions 6 of the polysilicon layer are inverse-tapered and are kept at a certain distance from each other, air gaps can be formed even if, unlike the conventional technology, the interlayer insulation film 12 is formed under film forming conditions with an excellent coverage such as by the CVD process.

As described above, according to the third embodiment, floating gate electrode layers are formed adjacent to each other, impurities such as arsenic and boron are injected to the adjacent floating gate electrode layers between the top layer and the base substrate surface to promote the etching process, while impurities such as nitrogen and oxygen are injected to the upper layer portion of each floating gate electrode layer the layered structure of which should not be thinned, so as to bring the upper portion into an amorphous state and delay the etching process, and the layered structure of each of the adjacent floating gate electrode layers is selectively thinned from the top layer to the base substrate by the etching process; as a result, the coupling ratio of the control gate electrodes and floating gate electrodes is improved, and the controllability of the voltage of the floating gate electrodes by the control gate electrodes is improved. Hence, a memory that has a control voltage with a large margin to stabilize the operation can be attained, allowing for, for example, a sufficient speed of memory writing and erasing even at a low voltage.

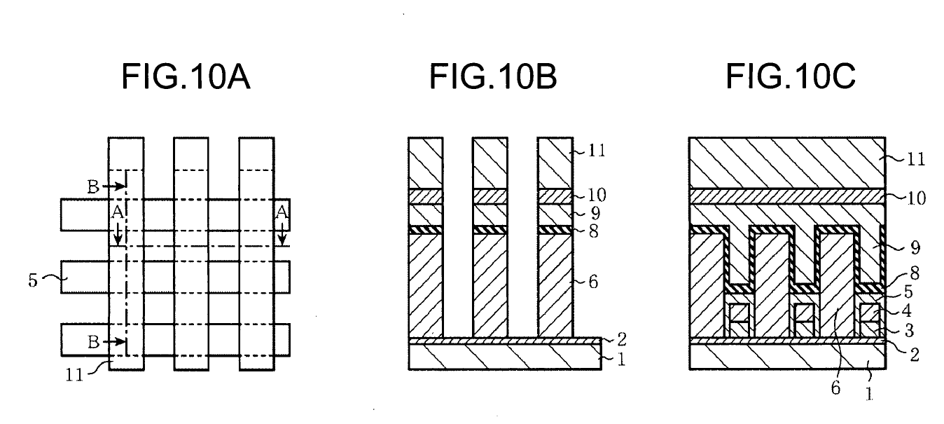

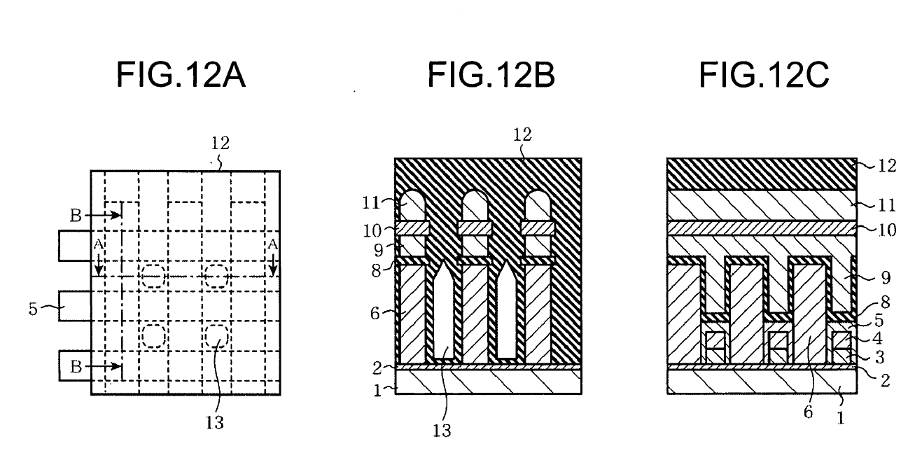

Each of FIGS. 10A to 12C is a view illustrating a constitution at a step of the method for producing a semiconductor device according to a fourth embodiment of the present invention; taking a volatile memory as an example of the semiconductor device, the process proceeds from the manufacturing step shown in FIG. 10C to the manufacturing step shown in FIG. 12A. Each of FIGS. 10A, 11A, and 12A is a top view of the semiconductor device, each of FIGS. 10B, 11B, and 12B is a cross section along a line A-A shown in respective FIGS. 10A, 11A, and 12A, and each of FIGS. 10C, 11C, and 12C is a cross section along a line B-B shown in respective FIGS. 10A, 11A, and 12A.

At the step shown in FIG. 10A, after forming an oxide film 2 of silicon oxide and the like on the silicon substrate 1, conductive films 3, which are to serve as assist gate electrodes, are formed of polysilicon whose resistance has been reduced by impurity doping or the like. The conductive films 3 are shaped like a strip along the line A-A shown in FIG. 10A, and a plurality of conductive films 3 are disposed in parallel along the line B-B as shown in FIG. 10C.

Next, gate-covering nitride films 4 are formed of, for example, silicon nitride (such as Si₃N₄) in such a manner as to cover the conductive films 3. Thereafter, as shown in FIG. 10C, oxide film layers 5 are formed of silicon oxide or the like along each of the conductive films 3 to cover the side surfaces of the conductive films 3 as well as the top surfaces and side surfaces of the gate-covering nitride films 4. Following this, as shown in FIGS. 10B and 10C, a polysilicon layer 6 is formed by the CVD (chemical vapor deposition) process or the like so as to function as a floating gate electrode unit.

After forming the above-mentioned constitution, the polysilicon is removed except for the portion of the polysilicon adjacent to the oxide film layer 5 by dry etching, and an ONO (oxide film-nitride film ((oxide film) insulation film 8 is formed on top of this film. Thereafter, a polysilicon layer 9 is formed on top of the ONO insulation film 8 by the CVD process or the like. On top thereon is formed a conductive film 10 of polysilicon that has a lowered resistance. Furthermore, an oxide film 11 is formed thereon and etched into patterns of control gate electrodes. As a result, the polysilicon layer 6, which is to function as a floating gate electrode unit, is formed to be exposed on the silicon substrate 1.

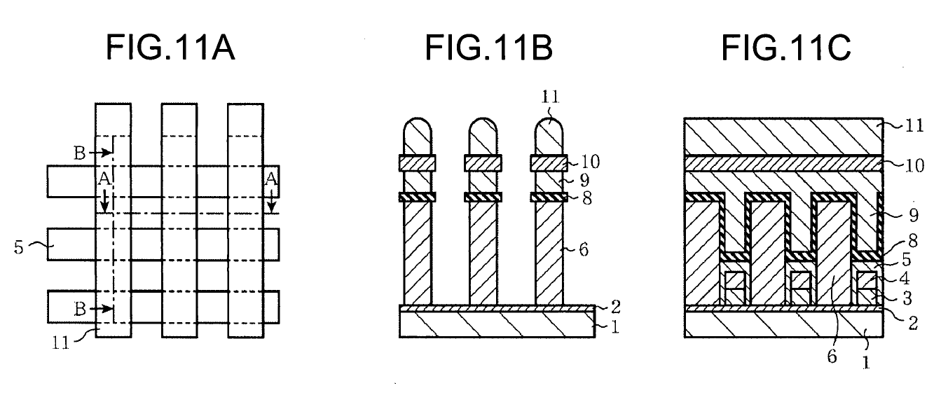

Next, at the step illustrated in FIG. 11A, with the floating gate electrode unit being exposed on the silicon substrate 1, a wet etching process is conducted. By using, for example, hydrofluoric acid, the polysilicon layers 6 and 9 are selectively etched owing to a difference in etching rates when compared to wet-etching of other film materials. As a result, the layered structures of the polysilicon layers 6, which are to function as floating gate electrode units, and the polysilicon layers 9, which are to function as control gate electrode units, are thinned, as shown in FIG. 11B. On the other hand, the layered structure of the ONO insulation film 8 that is less prone to being etched than the polysilicon is maintained and becomes shaped like eaves that hide the polysilicon layer 6 underneath it when viewed from above, as shown in FIG. 11B.

Thereafter, an interlayer insulation film 12 is formed at the step illustrated in FIG. 12A. At this time, because the ONO insulation film 8 has an eaves-like shape to hide the polysilicon layer 6 underneath it when viewed from above, air gaps 13 can be formed even if, unlike the conventional technology, the interlayer insulation film 12 is formed under film forming conditions with an excellent coverage such as by the CVD process.

As described above, according to the fourth embodiment, an ONO insulation film 8, which has a smaller etching rate than a polysilicon layer 6 that constitutes a floating gate electrode unit, is formed on the polysilicon layers 6, the layered structure of the polysilicon layers 6 is selectively etched by a wet etching process which utilizes this difference in etching rates, and an interlayer insulation film 12 is formed to have air gaps between the polysilicon layers 6 which are to function as floating gate electrode units by laminating insulation films by using as eaves the ONO insulation film 8 whose layered structure has been maintained in the wet etching process; thus, the parasitic capacitance between the contact portions of the ONO insulation film 8 and the floating gate electrodes is unchanged, while the capacitance between the floating gate electrodes is reduced. Thus, because the capacity ratio of the parasitic capacitance between the control gate electrodes and the parasitic capacitance between the floating gate electrodes is increased, the coupling ratio of the control gate electrodes and floating gate electrodes can be improved.

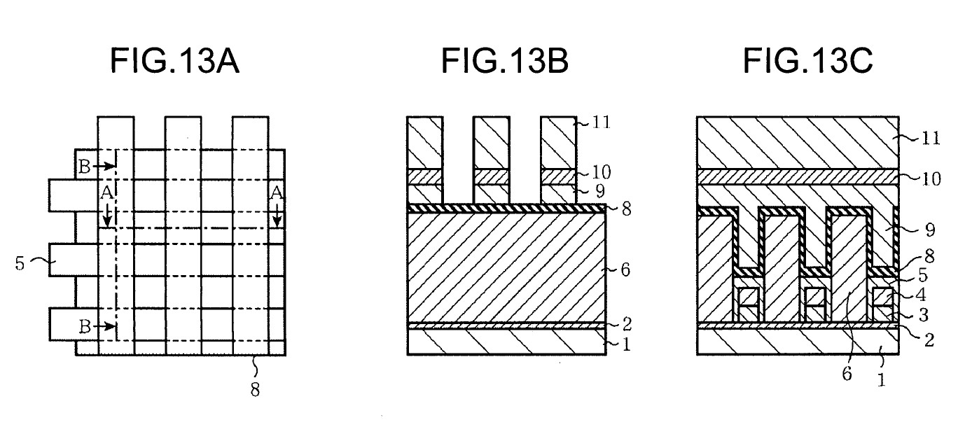

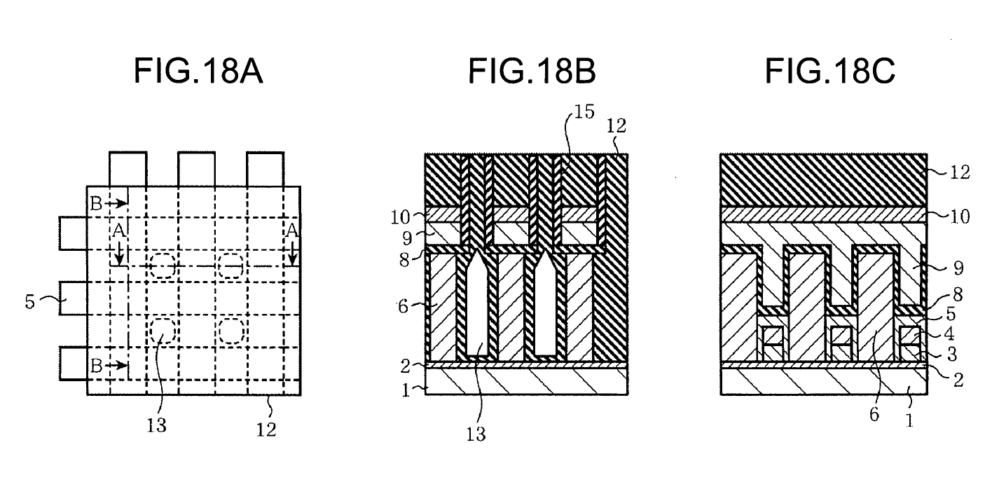

Each of FIGS. 13A to 18C is a view illustrating a constitution at a step of the method for producing a semiconductor device according to a fifth embodiment of the present invention; taking a volatile memory as an example of the semiconductor device, the process proceeds from the manufacturing step shown in FIG. 13A to the manufacturing step shown in FIG. 18C. Each of FIGS. 13A, 14A, 15A, 16A, 17A, and 18A is a top view of the semiconductor device, each of FIGS. 13B, 14B, 15B, 16B, 17B, and 18B is a cross-sectional view section along a line A-A shown in respective FIGS. 13A, 14A, 15A, 16A, 17A, and 18A, and each of FIGS. 13C, 14C, 15C, 16C, 17C, and 18C is a cross-section along a line B-B shown in respective FIGS. 13A, 14A, 15A, 16A, 17A, and 18A.

At the step shown in FIG. 13A, after forming an oxide film 2 of silicon oxide and the like on the silicon substrate 1, conductive films 3, which are to serve as assist gate electrodes, are formed of polysilicon whose resistance has been reduced by impurity doping or the like. Each of the conductive films 3 is shaped like a strip along the line A-A shown in FIG. 13A, and a plurality of conductive films 3 are disposed in parallel along the line B-B as shown in FIG. 13C.

Next, gate-covering nitride films 4 are formed of, for example, silicon nitride (such as Si3N4) in such a manner as to cover the conductive films 3. Thereafter, as shown in FIG. 13C, oxide film layers 5 are formed of silicon oxide or the like along each of the conductive films 3 to cover the side surfaces of the conductive films 3 as well as the top surfaces and side surfaces of the gate-covering nitride films 4. Following this, polysilicon layers 6 are formed by the CVD (chemical vapor deposition) process or the like so as to function as floating gate electrode units.

After forming the above-mentioned constitution, the polysilicon is removed except for the portion of the polysilicon adjacent to the oxide film layer 5 by dry etching, and an ONO (oxide film (nitride film (oxide film) insulation film 8 is formed on top of this film. Thereafter, a polysilicon layer 9 is formed on top of the ONO insulation film 8 by the CVD process or the like. On top thereon is formed a conductive film 10 of polysilicon that has a lowered resistance.

Furthermore, an oxide film 11 is formed thereon and etched into patterns of control gate electrodes. Here, the etching process is terminated at the ONO insulation film 8, as shown in FIG. 13B.

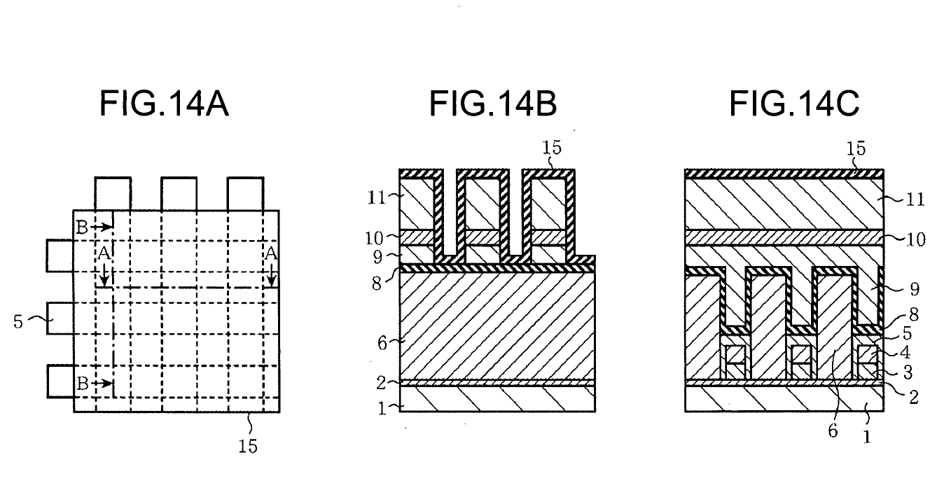

Next, at the step illustrated in FIG. 14A, a protective film 15 is formed in such a manner as to cover the top layer portion of the ONO insulation film 8. For instance, a silicon nitride film is formed by the CVD process or the like, and the layered portion consisting of the polysilicon layer 9, conductive film 10 and oxide film 11 on the ONO insulation film 8 is coated with a protective film 15 of the silicon nitride film, as shown in FIGS. 14B and 14C.

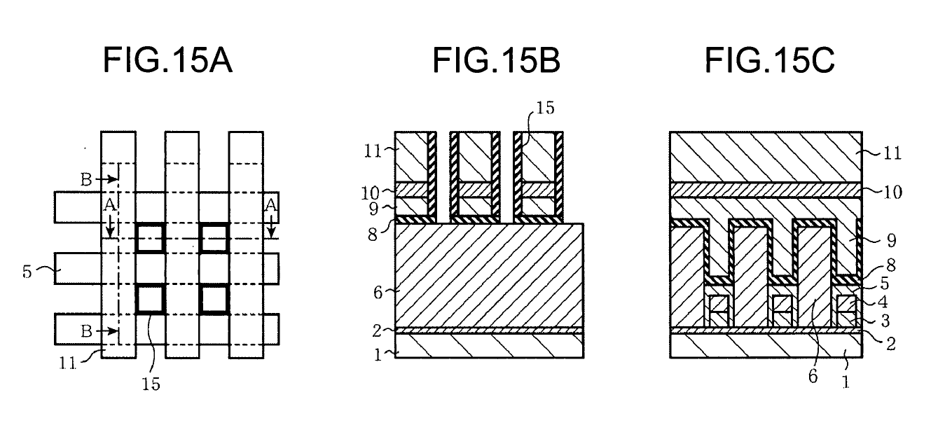

Then, at the step illustrated in FIG. 15A, the protective film 15 is etched back so that the protective film 15 remains only on the side walls of the layered portion consisting of the polysilicon layer 9, conductive film 10 and oxide film 11 on the ONO insulation film 8 (see FIG. 15B).

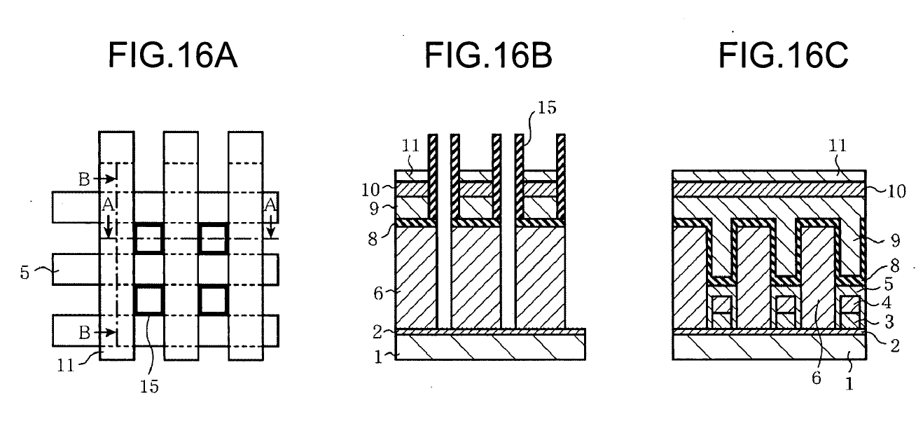

Thereafter, at the step shown in FIG. 16A, the constitution in which the protective film 15 is deposited only on the side walls of the layered portion consisting of the polysilicon layer 9, conductive film 10 and oxide film 11 on the ONO insulation film 8 is subjected to an etching process to obtain control gate electrode patterns. As a result, the polysilicon layers 6 which are to function as floating gate electrode units are exposed on the silicon substrate 1, as shown in FIG. 16B.

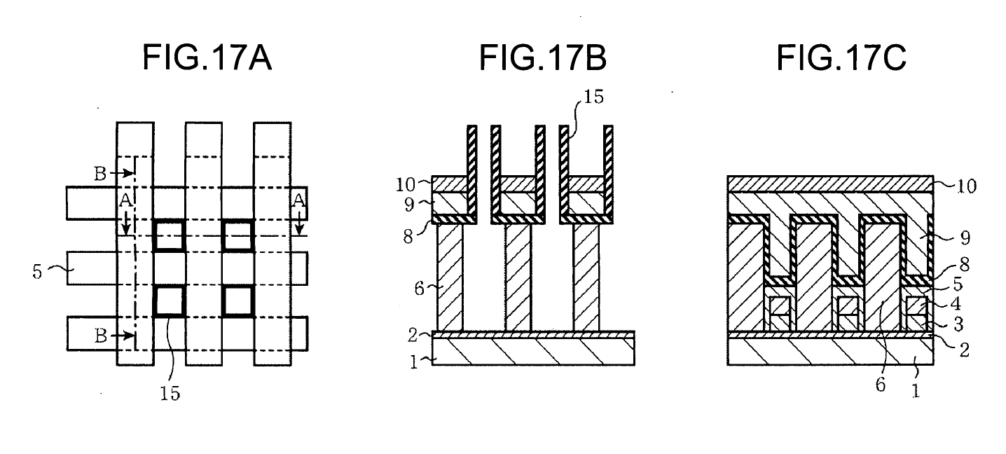

At the subsequent step illustrated in FIG. 17A, the wet etching process is conducted with the floating gate. electrode units being exposed on the silicon substrate 1. For instance, by using hydrofluoric acid or the like, the polysilicon layers 6 are selectively etched owing to the difference in etching rates of wet-etching the protective film 15 and the polysilicon layers 6. Hence, the layered structures of the polysilicon layers 6 which are to function as floating gate electrode units are thinned, as shown in FIG. 17B.

On the other hand, the shape of the constituent layers above the ONO insulation film 8, which are coated with the protective film 15 less prone to being etched than polysilicon, is maintained and becomes shaped like eaves that hide the polysilicon layer 6 underneath it when viewed from above, as shown in FIG. 17B. Here, the oxide film 11 is completely removed (see FIG. 17C).

Thereafter, an interlayer insulation film 12 is formed at the step illustrated in FIG. 18A. At this time, because the constituent layers above the ONO insulation film 8 which are coated with the protective film 15 have an eaves-like shape to hide the polysilicon layer 6 underneath the ONO insulation film 8 when viewed from above, air gaps 13 can be formed, as shown in FIG. 18B, even if, unlike the conventional technology, the interlayer insulation film 12 is formed under film forming conditions with an excellent coverage such as by the CVD process.

As described above, according to the fifth embodiment, a protective film 15 that is to delay the wet etching process is formed above the ONO insulation film 8 the layered structure of which should not be thinned, the layered structure of the polysilicon layer 6 is selectively thinned by the wet etching process utilizing a difference in etching rates of the protective film 15 and the polysilicon layer 6 that constitutes a floating gate electrode unit, and an interlayer insulation film 12 is formed to have air gaps between the polysilicon layers 6 which are to function as floating gate electrode units by laminating insulation films by using as eaves the constituent layers above the ONO insulation film 8 that are coated with the protective film 15 whose layered structure has been maintained in the wet etching process; thus, the parasitic capacitance between the contact portions of the ONO insulation film 8 and the floating gate electrodes is unchanged, while the parasitic capacitance between the floating gate electrodes is reduced. Thus, because the capacity ratio of the parasitic capacitance between the control gate electrodes and the parasitic capacitance between the floating gate electrodes is increased, the coupling ratio of the control gate electrodes and floating gate electrodes can be improved.

It should be noted that, although air gaps are formed by increasing the distance between floating gate electrodes in the first to fifth embodiments, the present invention is not limited thereto. In other words, if there is any place in which the parasitic capacitance should be reduced between at least one of the wiring layers and the isolation pattern layers, the present invention may be applied and at least one of the adjacent wiring layers and the isolation pattern layers themselves may be thinned so as to increase the distance therebetween in order to reduce the parasitic capacitance therebetween.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor device comprising:
an interlayer insulation film including an air gap between portions of adjacent wiring layers or isolation pattern layers or both that are distanced from each other by thinning a layered structure of each of the wiring layers or the isolation pattern layers or both selectively from a top layer to a substrate so that the portions of the wiring layers or the isolation pattern layers or both are distanced from each other.

2. The semiconductor device according to claim 1, further comprising:
a volatile memory structure including a wiring layer that forms a plurality of floating gate electrodes for a charge storage on a semiconductor substrate; and
an interlayer insulation film including an air gap between portions of adjacent wiring layers that form the floating gate electrodes and are distanced from each other by thinning the layered structures of the wiring layers selectively from the top layer to the base substrate surface.

3. The semiconductor device according to claim 2, wherein the interlayer insulation film has an air gap between floating gate electrode units of the adjacent wiring layers.

4. A method for producing a semiconductor device which comprises an interlayer insulation film having an air gap between any one of adjacent wiring layers and isolation pattern layers disposed on a semiconductor substrate, the method comprising:
thinning the layered structures of at least one of the wiring layers and the isolation pattern layers selectively from a top layer to a base substrate surface by a wet etching process by using a difference in etching rates so that a distance is kept between at least one of the wiring layers and the isolation pattern layers from the top layer to the base substrate surface; and
forming an interlayer insulation film having the air gap between at least one of the distanced wiring layers and the isolation pattern layers by laminating insulation films between at least one of the wiring layers and the isolation pattern layers.

5. The method according to claim 4, wherein
the semiconductor device comprises a volatile memory structure having wiring layers which constitute a plurality of floating gate electrodes on the semiconductor substrate for storing electric charge,
the layered structures of the adjacent wiring layers that constitute the floating gate electrodes are thinned selectively from the top layer to the base substrate surface by the wet etching process by using the difference in etching rates so that the distance is kept between the wiring layers from the top layer to the base substrate surface, and
the interlayer insulation film having the air gap between the distanced wiring layers is formed by laminating insulation films between the wiring layers.

6. The method according to claim 4, wherein impurities for promoting the wet etching process are injected to at least one of the adjacent wiring layers and the isolation pattern layers between the top layer to the base substrate surface, and at least one of the layered structures of the wiring layers and the isolation pattern layers are thinned selectively from the top layer to the base substrate surface by the wet etching process by using the difference in etching rates created by the impurity injection.

7. The method according to claim 4, wherein impurities for delaying the wet etching process are injected to at least one of the upper layer portions of the adjacent wiring layers and the isolation pattern layers that are not targeted to be thinned, and at least one of the layered structures of the wiring layers and the isolation pattern layers are thinned selectively from the top layer to the base substrate surface by the wet etching process by using the difference in etching rates created by the impurity injection.

8. The method according to claim 4, further comprising:
injecting impurities for promoting the wet etching process to at least one of the adjacent wiring layers and the isolation pattern layers between the top layer to the base substrate surface;
injecting impurities for delaying the wet etching process to the upper layer portions of at least one of the adjacent wiring layers and the isolation pattern layers that are not targeted to be thinned; and
thinning the layered structures of at least one of the wiring layers and the isolation pattern layers selectively from the top layer to the base substrate surface by the wet etching process by using the difference in etching rates created by the impurity injection.

9. The method according to claim 6, wherein at least one of the adjacent wiring layers and the isolation pattern layers from the base substrate surface to the top layer are formed of polysilicon, and at least one of arsenic, phosphorus, boron and BF2+ is injected thereto as impurities for promoting the wet etching process.

10. The method according to claim 8, wherein at least one of the adjacent wiring layers and the isolation pattern layers from the base substrate surface to the top layer are formed of polysilicon, and at least one of arsenic, phosphorus, boron and BF2+ is injected thereto as impurities for promoting the wet etching process.

11. The method according to claim 7, wherein the upper layer portions of at least one of the adjacent wiring layers and the isolation pattern layers are formed of polysilicon, and at least one of argon, nitrogen and oxygen is injected thereto as impurities for delaying the wet etching process so as to bring the upper layer portions into an amorphous state and delay the etching process.

12. The method according to claim 8, wherein the upper layer portions of at least one of the adjacent wiring layers and the isolation pattern layers are formed of polysilicon, and at least one of argon, nitrogen and oxygen is injected thereto as impurities for delaying the wet etching process so as to bring the upper layer portions into an amorphous state and delay the etching process.

13. The method according to claim 4, wherein
in at least one of the adjacent wiring layers and the isolation pattern layers, a constituent layer which has an etching rate smaller than that of a constituent layer whose layered structure is to be thinned is formed on top of the constituent layer whose layered structure is to be thinned;
the layered structure of the constituent layer to be thinned in at least one of the adjacent wiring layers and the isolation pattern layers is selectively thinned by the wet etching process by using the difference in etching rates of the constituent layers of at least one of the adjacent wiring layers and the isolation pattern layers;
the interlayer insulation film having the air gap between the distanced wiring layers is formed between at least one of the wiring layers and the isolation pattern layers by laminating the insulation films between at least one of the wiring layers and the isolation pattern layers by using the constituent layer formed on top of the constituent layer to be thinned whose layered structure has been maintained in the wet etching process, as eaves.

14. The method according to claim 4, wherein a protective film for delaying the wet etching process is formed on the upper layer portion whose layered structure is not targeted to be thinned in at least one of the adjacent wiring layers and the isolation pattern layers, and the layered structures of at least one of the wiring layers and the isolation pattern layers are thinned selectively from the top layer to the base substrate surface by the wet etching process by using the difference in etching rates created by the protective film when compared to other portions.
